(19) United States
(12) Patent Application Publication
(10) Pub. No.: US 2025/0220975 A1
(43) Pub. Date: Jul. 3, 2025

(54) SEMICONDUCTOR FILM, AND METHOD FOR PRODUCING SEMICONDUCTOR FILM

(71) Applicant: IDEMITSU KOSAN CO.,LTD., Tokyo (JP)

(72) Inventor: Kazuyoshi INOUE, Chiyoda-ku, Tokyo (JP)

(73) Assignee: IDEMITSU KOSAN CO.,LTD., Tokyo (JP)

(21) Appl. No.: 18/852,660

(22) PCT Filed: Feb. 21, 2023
(86) PCT No.: PCT/JP2023/006147

§ 371 Date: Sep. 30, 2024

(30) Foreign Application Priority Data
Apr. 1, 2023 (JP) 2022-062090

(51) Int. Cl. H10D 30/67; C23C 14/08; C23C 14/34; H10D 62/80

(52) U.S. Cl. CPC H10D 30/6755; C23C 14/086; C23C 14/3414; H10D 30/6757; H10D 62/875

(57) ABSTRACT

A semiconductor film comprising a solid phase crystallized product of tin and hydrogen-doped indium oxide.

### TECHNICAL FIELD

The present invention relates to a semiconductor film. More specifically, the present invention relates to a semiconductor film including a solid phase crystallized tin-doped indium oxide containing a hydrogen atom, a method for producing the semiconductor film, a sputtering target used for producing the semiconductor film and a thin film transistor.

### BACKGROUND ART

A tin-doped indium oxide (ITO) is used as a transparent electrode in a display device, a touch panel, or the like. In addition, it is also used as a constituent member of a semiconductor device such as a semiconductor layer (also referred to as channel layer) of a thin film transistor (TFT) (for example, see Patent Documents 1 to 6).

Patent Document 1 discloses a thin film transistor (TFT) including a gate electrode, a gate insulating film, a source electrode, a drain electrode, and a semiconductor layer of a low-conductivity ITO film, wherein the carrier concentration of the semiconductor layer is 10¹⁸ cm⁻³ or less, and the semiconductor layer is a light-transmitting film.

Patent Document 2 discloses that another covalent bond oxide of a non-transition metal provided with a dopant atom is used for the semiconductor material in the channel-region. In addition, it teaches that the amount of the dopant atom can be 0.001% to 0.3% to obtain a sufficiently high conductivity for use as the semiconductor material in switching device.

Patent Document 3 discloses a TFT including a crystalline indium oxide semiconductor film and having the amount of a metal element having positive tetravalent or more of 10 atom ppm or less based on the metal element contained in the semiconductor film. It has been found that an impurity of a semiconductor film made of crystalline indium oxide, specifically, a metal element having positive tetravalent or more, affects the trapping density of the semiconductor film, and it is proposed to use a highly pure crystalline indium oxide.

Patent Document 4 discloses an In₂O₃ sintered body containing tin as an additive element, wherein tin is added thereto with the number of atoms of 0.01 to 0.2% as a ratio based on the total number of atoms of all metal elements in the sintered body, whereby the relative density is 98% or more.

Patent Document 5 discloses an oxide semiconductor film-forming process in which a film-forming body is formed by DC sputtering a sputtering target made of a metal oxide at a water partial pressure of 3×10⁻⁴ to 5×10⁻² Pa in a sputtering apparatus, and the film-forming body is crystallized.

Patent Document 6 discloses a stacked structure having an oxide semiconductor thin film layer and a TFT using the same as a channel layer, and discloses the stacked structure in which a material constituting the oxide semiconductor thin film layer is composed of indium oxide, Ga-doped indium oxide, Al-doped indium oxide, Zn-doped indium oxide, and Sn-doped indium oxide.

### RELATED ART DOCUMENTS

### Patent Documents

[Patent Document 1] JPH05-251705 A
[Patent Document 2] JP H11-505377 A
[Patent Document 3] WO 2010/047063 A1
[Patent Document 4] JP 2011-093730 A
[Patent Document 5] JP 2011-222557 A
[Patent Document 6] JP 2012-253315 A

### SUMMARY OF THE INVENTION

It is known that high-purity indium oxide can be formed by sputtering in the presence of water or hydrogen, and then crystallize of the film to form a high mobility oxide semiconductor film. However, heat treatment at high temperatures (for example, 350° C. or higher) performed to stabilize TFT may reduce the mobility. For this reason, it is sometimes difficult to achieve both high mobility and stable operation in TFT.

An object of the present invention is to provide a semiconductor film in which the reduction in mobility is small even when heat-treated at a high temperature for stabilization of TFT and a method for producing the same. It is another object of the present invention to provide a sputtering target capable of forming a stable film when the semiconductor film is produced.

According to the present invention, the following semiconductor film and the like is provided.

1. A semiconductor film comprising a solid phase crystallized product of tin and hydrogen-1. doped indium oxide.
2. The semiconductor film according to 1, wherein the amount of tin atom (Sn) based on the total amount of indium atom (In) and tin atom (Sn) [Sn/(In+Sn): molar ratio] in the solid phase crystallized product is 0.000005 to 0.008, and
the concentration of the hydrogen atom (H) measured by the secondary ion mass spectrometry is 0.5×10²⁰ to 50×10²⁰ atoms/cc.
   3. The semiconductor film according to 1 or 2, wherein the cross-section thereof is tapered shape.
   4. A method for producing the semiconductor film according to any one of 1 to 3, comprising: sputtering a tin-doped indium oxide (ITO) sputtering target in a film forming gas containing 0.5 to 12% of a gas supplying a hydrogen atom at a partial pressure to form an amorphous film, and heating the amorphous film to crystallize it.
   5. The method for producing according to 4, which further comprises: forming an etching cross-section with a tapered shape in a photolithography step after forming the amorphous film.
   6. A tin-doped indium oxide sputtering target for forming an amorphous film of tin and hydrogen-doped indium oxide, wherein the amount of tin atom (Sn) based on the total amount of indium atom (In) and tin atom (Sn) [Sn/(In+Sn): molar ratio] is 0.000005 to 0.008.
   7. A thin film transistor comprising the semiconductor film according to any one of 1 to 3.

According to the present invention, it is possible to provide a semiconductor film in which the reduction in mobility is small even when heat treatment is performed at a high temperature for stabilization of TFT. In addition, it is possible to provide a sputtering target capable of forming a stable film when the semiconductor film is produced.

### BRIEF DESCRIPTION OF THE DRAWINGS

FIG. 1 is a schematic cross-sectional view of a TFT according to one embodiment of the present invention.

FIG. 2 is a SEM photograph of a cross-section of a sputtering target produced in Example 1-1.

FIG. 3 is a schematic cross-sectional view of a TFT produced in Example.

FIG. 4 is a transfer curve of TFT produced in Example 2-1.

FIG. 5 is a graph of Vg and u in TFT produced in Example 2-1.

FIG. 6 is a transfer curve of TFT produced in Comparative Example 3-1

FIG. 7 is a graph of Vg and u in TFT produced in Comparative Example 3-1.

### MODE FOR CARRYING OUT THE INVENTION

As used herein, the term “film” or “thin film” and the term “layer” are sometimes interchangeable with each other.

In a sintered body and an oxide thin film as used herein, the term “compound” and the term “crystal phase” are sometimes interchangeable with each other.

As used herein, the term “oxide sintered body” is sometimes simply referred to as “sintered body”.

As used herein, the term “sputtering target” is sometimes simply referred to as “target”.

As used herein, the term “electrically connected” encompasses a connection via “an object of some electric action”. The “object of some electric action” is not particularly limited as long as the object allows communication of electric signals between connected components. For example, the “object of some electrical action” includes an electrode, a wiring, a switching element (transistor or the like), a resistance element, an inductor, a capacitor, and an element having various other functions.

In the present specification and the like, the functions of the source and drain of a transistor may be replaced when a transistor of a different polarity is employed or when a current direction changes in a circuit operation. Accordingly, the terms “source” and “drain” as used herein may be interchangeably used.

In the present specification, the term “x to y” refers to a numerical range of “x or more and y or less”. An upper limit value and a lower limit value described for the numerical range may be arbitrarily combined.

In addition, the present invention also encompasses modes obtained by combining two or more individual modes of the present invention described below.

### 1. Semiconductor Film

The semiconductor film according to the present embodiment includes a solid phase crystallized product of tin and hydrogen-doped indium oxide (hereinafter, tin and hydrogen-doped indium oxide are sometimes abbreviated as H:ITO).

Here, the solid phase crystallization means that an amorphous body in a solid state is crystallized by heated. On the other hand, the vapor phase crystallization means, for example, crystallization by film formation.

It is known that vapor-phase crystallized indium oxide or tin-doped indium oxide (ITO) cannot be etched without using a strong acid such as aqua regia. When the etching is performed with a strong acid, the source electrode, the drain electrode, the gate electrode, or the like constituting TFT may be damaged, and thus the use thereof is limited. Further, damages to interlayer insulating film, the gate-insulating film, and the like are also conceivable.

On the other hand, since the amorphous film used for solid phase crystallization can be etched by an organic acid such as oxalic acid which is a weak acid, it is possible to stably production TFT because there is no effect on the source electrode, the drain electrode, the gate electrode, and the like constituting TFT.

In the present aspect, for example, a solid-phase amorphous film formed by sputtering is etched and then heated to crystallize the amorphous film, whereby a semiconductor film including a solid-phase crystallized product of H:ITO can be obtained.

The tin and hydrogen-doped indium oxide (H:ITO) means that indium oxide is doped with tin atom and hydrogen atom.

The doping of the tin and the hydrogen and the doping amount (amount) can be measured by elemental analysis such as secondary ion mass spectrometry (SIMS), high frequency inductively coupled mass spectrometry (ICP-MS), or the like.

The thickness of the semiconductor film of the present aspect is preferably 5 nm to 150 nm. Within this range, a uniform film can be easily obtained, and the film formation time is appropriate and productivity is improved. In addition, the mobility when used for TFT may be increased. It is preferably 10 nm to 100 nm, more preferably 15 nm to 80 nm.

It is known that adding tin atom to indium oxide improves sinterability (crystallinity) of sintered body crystal. Similarly, it is considered that adding tin atom to indium oxide film improves the crystallinity of the film.

When the added amount of the tin atom is small, for example, a semiconductor film that cannot withstand heat of 350° C. or more may be formed. On the other hand, when the tin atom is excessively added, a transparent conductive film may be formed and may not function as a semiconductor film.

In view of the above-described, in the semiconductor film of the present embodiment, it is preferable that the amount of tin atom (Sn) based on the total amount of indium atom (In) and tin atom (Sn) in the solid phase crystallized product [Sn/(In+Sn): molar ratio] be 0.000005 to 0.008. It is more preferably 0.00001 to 0.005, still more preferably 0.00002 to 0.003, and particularly preferably 0.00002 to 0.001. The upper limit thereof may be less than 0.001.

In addition, it is known that it usually activates tin (Sn⁴⁺) dopants by crystallization in ITO, and Sn⁴⁺ replaces In sites in In₂O₃ crystal to generate electron carriers, thereby forming a transparent conductive film. For example, when all of the added tin atom is activated and two electron carriers are released per tin dopant, and even when the added amount of SnO₂ of the raw material is 0.01% by mass, the number of tin atoms per 1 cm³ is 6.5×10¹⁸, so that the electron concentration thereof is considered to be 10¹⁸ or more, and it is expected that a transparent conductive film is formed.

Surprisingly, however, it is believed that the tin dopant is not activated in the present aspect, and as a result, it can be used as a semiconductor film.

In addition, in the step of crystallization, Sn⁴⁺ is reduced to Sn²⁺ by H-dopant, and even when In site of In₂O₃ crystal is substituted with Sn²⁺, the electron carrier is not generated, and there is also a possibility that it works as a semiconductor film, so that hydrogen-doping is critical.

Furthermore, it is well known that in crystalline indium oxide thin films, carriers are generated due to oxygen defect. Carrier generation due to oxygen defect may be suppressed by filling with-OH group.

On the other hand, In defect may also occur. It is also conceivable that In³⁺ defects in the crystal are filled with 3H⁺. The ionic radius of H⁺ ion is 0.38 Å, and the ionic radius of In³⁺ ion (six coordination In³⁺) is 0.80 Å. From this, it is possible that H⁺ ions having small ion radius fill In defect and remain stable as crystal.

In view of the above, the concentration of the hydrogen atom (H) contained in the semiconductor film is preferably 0.5×10²⁰ to 50×10²⁰ atoms/cc. When it is less than 0.5×10²⁰ atoms/cc, it may not be effective in adding hydrogen. Further, in order to be less than 0.5×10²⁰ atoms/cc after the hydrogen additive film formation, the hydrogen needs to be desorbed from the crystallized indium oxide film at a high temperature, a high vacuum, or the like, and thus the productivity may be lowered. On the other hand, when it is more than 50×10²⁰ atoms/cc, there is a possibility that the amount of hydrogen due to the physically absorbed water is contained, and consequently, the mobility may be lowered and the driving stability of TFT may be lowered. It is more preferably 1×10²⁰ to 30×10²⁰ atoms/cc, still more preferably 1×10²⁰ to 20×10²⁰ atoms/cc, and particularly preferably 1×10²⁰ to 10×10²⁰ atoms/cc.

The concentration of the hydrogen atom (H) contained in the semiconductor film is defined as the hydrogen concentration (atoms/cc) measured by the secondary ion mass spectrometry (SIMS). The concentration of the hydrogen atom (H) contained in the solid-phase crystallized product may not be constant but may be changed in the depth direction of the film thickness, but it is expressed as the average value.

In the semiconductor film of the present aspect, it is preferable that the etching cross-section thereof has a tapered shape. Thus, when the constituent films of TFT such as interlayer insulating film, the gate-insulating film and the like are formed, it is easy to secure the insulating property with the other films.

The taper angle (the inner angle between the bottom and the side of the cross-section) is 45° to 90°. When it is less than 45°, the width of the tapered shape is increased, which may be unsuitable for producing a TFT having a short channel width. On the other hand, when it is more than 90°, TFT may not operate due to insufficient coverage due to interlayer insulating film or the like. The taper angle is preferably from 50° to 85°, more preferably from 55° to 80°.

### 2. Method for Producing Semiconductor Film

The semiconductor film of the present invention can be produced, for example, by sputtering an ITO target in a film-forming gas (sputtering gas) containing 0.5 to 12% of a gas for supplying a hydrogen atom at a partial pressure to form an amorphous film, and then by heating the amorphous film to crystallize it.

Water (water vapor), hydrogen, or the like can be used as the gas for supplying the hydrogen atom. The gas for supplying the hydrogen atom is preferably supplied to the sputtering apparatus in the state of a gas. The concentration of the gas supplying the hydrogen atom during sputtering is adjusted to the desired crystallization temperature.

For example, when the gas supplying the hydrogen atom is supplied at less than 0.5% as the partial pressure in sputtering, the film tends to crystallize at a low temperature and thus a vapor-phase crystallized film may be obtained. As a consequence, when crystallization occurs during the heat treatment in the photolithography step, the etching cannot be performed, or when a residue is generated and an etching failure occurs, it may hinder the production of TFT.

On the other hand, when the partial pressure of the gas supplying the hydrogen atom is increased, the crystallization temperature tends to increase. When the gas supplying the hydrogen atom is supplied at a partial pressure of more than 15%, the crystallization temperature due to heating becomes equal to or higher than a desired temperature, and the amorphous film may not crystallize, or the crystallinity may be lowered even when the amorphous film crystallizes. Consequently, the mobility of TFT may be lowered.

The amount of gas supplying the hydrogen atom is preferably 0.5 to 12%, more preferably 1 to 12%, still more preferably 1 to 10%, and particularly preferably 2 to 8% at the partial pressure.

The film forming gas may further be mixed with an oxidizing gas. As the oxidizing gases, oxygen, N₂O, NO₂, and the like can be used. Among them, oxygen is preferable.

When the hydrogen is used as the gas supplying the hydrogen atom, it is preferably used with oxygen. When sputtering is performed by supplying only hydrogen without supplying oxygen, In₂O₃ itself are reduced to generate oxygen defect, and therefore it may result in a transparent conductive film.

When the semiconductor film is formed, oxygen and hydrogen, or water and hydrogen are preferably used in combination.

When oxygen and hydrogen are used in combination, the amount of oxygen supplied during sputtering is adjusted by the amount of hydrogen used in combination. As shown in the following formula, oxygen reacts with hydrogen to form water.

H₂+½O₂→H₂O

Therefore, the supply amount of hydrogen is preferably 2 times or more of oxygen. Thus, hydrogen doping can be effectively performed.

On the other hand, when water is used as the gas supplying the hydrogen atom, hydrogen can be doped by hydrogen atom of the water molecules, but further hydrogen can be doped more effectively by supplying hydrogen.

The conditions for sputtering ITO target in the film forming gas in which at least one of the gas supplying the hydrogen atom and the oxidizing gas is coexisting are not particularly limited, and it can be appropriately adjusted for using the use device, the composition of the target, the composition of the sputtering gas, and the like.

The film forming methods are not particularly limited, and examples thereof include DC sputtering, AC sputtering, RF sputtering, ICP sputtering, reactive sputtering, and the like. Among these, pulsed DC sputtering can be suitably used as DC sputtering.

For pulsed DC sputtering, the pulse frequency is, for example, 1 kHz to 1 MHZ, preferably 10 KHz to 500 kHz, and more preferably 30 kHz to 300 kHz. In addition, the driving duration during the pulse (the proportion of the actual sputtering driving, which is expressed as Duty (%)) is usually 30% to 95%, preferably 40% to 95%, and more preferably 50% to 90%.

When the Duty is 30% or less, the sputtering rate may decrease, the sputtering time may be prolonged, and resulting in a decrease in productivity. When the Duty is 95% or more, the sputtering rate is excessively increased, yellow flakes increase during sputtering, and it may cause nodules to adhere as foreign matters on the targets.

The film-forming power output of the sputtering with respect to the target area is, for example, 1 W/cm² to 10 W/cm². When it is less than 1 W/cm², the sputtering rate may decrease, the sputtering time may be prolonged, and resulting in a decrease in productivity. In addition, the density of the obtained film may decrease. When it is 10 W/cm² or more, the power output may be too high and a large amount of yellow flakes may be generated.

When the film-forming power output is adjacent to 8 W/cm², it is possible to adjust the film-forming power output to suppress generation of yellow flakes by shortening Duty. When the film-forming power output is adjacent to 1 W/cm², by increasing Duty, it is possible to adjust to maintain high productivity by increasing the sputtering rate, or to suppress the generation of yellow flakes and nodules.

After forming the amorphous film by sputtering, the amorphous film is crystallized by heating to obtain a semiconductor film (a film containing a solid phase crystallized product of H:ITO) of the present invention. Note that, the crystallization step by heating may be referred to as annealing.

The crystallization temperature is, for example, 200° C. to 500° C. When the crystallization temperature is less than 200° C., it may not crystallize. On the other hand, when the crystallization temperature is more than 500° C., the durability of the heating device may be a problem. It is preferably 250° C. to 450° C.

In the crystallization step, for example, an oxide semiconductor film having good crystallinity can be obtained by holding in the crystallization temperature region for a constant time or raising the temperature at a temperature increase rate of 10° C./min or less.

Since the crystallization temperature varies depending on the amount of gas supplying the hydrogen atom supplied during film-forming, the combination of it with the film-forming conditions is critical.

When holding at the crystallization temperature for a certain period of time, the holding time is preferably 5 to 60 minutes. When it is less than 5 minutes, crystallize may not start, and when it is more than 60 minutes, the retention time is prolonged, it causes a decrease in productivity. It is preferably 8 to 45 minutes, more preferably 10 to 30 minutes.

It is also preferable to carry out the heat treatment of the crystallization in two stages. The crystal can be grown by the first-stage heat treatment, and the crystal can be stabilized by the second-stage heat treatment. The temperature may be changed by each heat treatment. For example, the first-stage heat treatment may be crystallized at a low temperature and the second-stage heat treatment may be crystallized at a high temperature, or the first-stage heat treatment may be crystallized at a high temperature and the second-stage heat treatment may be crystallized at a low temperature to stabilize the crystal.

Between the first-stage heat treatment and the second-stage heat treatment, a SiO₂ film may be formed by N₂ treatment or CVD treatment to provide an interlayer insulating film, a gate-insulating film, and the like. In the step of forming SiO₂ film by N₂ treatment or CVD treatment, a crystalline-structure defect may occur in the semiconductor film, or an extra oxygen-element or hydrogen-element may exist between the crystalline layers or between the other layers. By performing the heat treatment in two stages, the second-stage heat treatment may have an effect on stabilization of the semiconductor film.

The method for producing it of the present aspect may include: forming an amorphous film and then processing an etching cross-section with a tapered shape in a photolithography step. Further, after processing into a tapered shape, the amorphous film may be crystallized by heating (annealing).

For the adjustment of the taper angle, the taper angle tends to increase when the adhesiveness between the resist and the amorphous film is increased. As adhesion decreases, the taper angle tends to decrease. Therefore, the taper angle can be adjusted by controlling the adhesiveness.

Further, when the temperature of the etchant is increased, the taper angle tends to increase, and when the temperature is decreased, the taper angle tends to decrease. The adhesiveness between the resist and the amorphous film and the temperature of the etchant can be controlled in combination.

When the semiconductor film formed by the above-described producing method is used in TFT, the mobility is not reduced or the reduction thereof is small even when it is exposed to high temperatures. Therefore, even when high-temperature annealing is performed to stabilize TFT, high mobility can be maintained, and therefore, both high mobility and stable operation can be achieved in TFT.

The high-temperature annealing temperature for stabilization of TFT may be 250° C. or higher, may be 300° C. or higher, or may be 350° C. or higher. It is usually 500° C. or less.

### 3. Sputtering Target

A sputtering target according to an aspect of the present invention is a tin-doped indium oxide sputtering target for forming an amorphous film of tin and hydrogen-doped indium oxide. That is, it is an ITO target used in the method for producing it in Item 2 above described.

From the viewpoint similar to that of the semiconductor film in Item 1 above described, it is preferable that the amount of tin atom (Sn) based on the total amount of indium atom (In) and tin atom (Sn) [Sn/(In+Sn): molar ratio] in the target of the present aspect be 0.000005 to 0.008. It is more preferably 0.00002 to 0.005, still more preferably 0.00003 to 0.005, and particularly preferably 0.00005 to 0.005.

When tin atom is added, it has the effect of reducing the target resistance, because the tin atom is dissolved in indium oxide to generate carriers.

In the target of the present aspect, the relative density is preferably 99.0% or more. As a result, stable film-forming is enabled. The relative density is more preferably 99.1% or more. The relative density is a ratio (%) of the measured value to the theoretical density (7.18 g/cm³).

Further, the bulk (specific) resistance value of the target is preferably 10 mΩcm or less. As a result, stable film-forming is enabled. The bulk resistance value is more preferably 5 mΩcm or less. The bulk resistance value is a value measured by the method described in the Examples.

The method for producing the target of the present aspect is not particularly limited, and a general method can be used. Specifically, when the amount of tin atom is more than 0.0001, the raw material indium oxide and tin oxide are mixed and pulverized, and the mixed powder is formed and then sintered to form an oxide sintered body, and after cutting and polishing as necessary, it can be produced by fixing to a backing plate.

On the other hand, when the amount of tin atom is less than 0.0001, the relative density of the target may be decreased or the bulk-resistance thereof may be increased. However, when an apparatus that can be mixed and pulverized at high energy such as a planetary ball mill is used, and fine sintering powder is formed from the raw material, it is possible to produce a sintered body (target) having high density and low resistance.

The shape of the target can be selected from a round shape, a rectangular shape, a cylindrical shape, and the like in accordance with the sputtering apparatus.

The purity of the raw material indium oxide is preferably 99.9% or more, more preferably 99.99% or more, and still more preferably 99.995% or more. Due to the high purity, scattering of carriers due to impurities and the like can be suppressed, and a high-performance semiconductor film can be manufactured.

The crystalline particle size in the target (sintered body) is preferably 0.5 to 20 μm. When it is less than 0.5 μm, the strength of the sintered body is reduced because the crystalline particle is too small, and therefore cracks or microcracks may occur. On the other hand, when a large crystalline particle of more than 20 μm is obtained, the crystalline may be abnormally grown and cracked, or microcracks may be generated inside the crystalline. In a target in which microcracks have occurred, a large amount of yellow flakes or nodules may be generated. Removal of yellow flakes and nodules may take time, shorten the real time of sputtering, and reduce productivity. The crystalline particle size is more preferably 1 to 15 μm, and still more preferably 1 to 10 μm.

### 4. Thin Film Transistor

A TFT according to the present aspect includes the above-described semiconductor film of the present invention. The semiconductor film of the present invention is preferably used as the semiconductor layer (channel layer) of TFT.

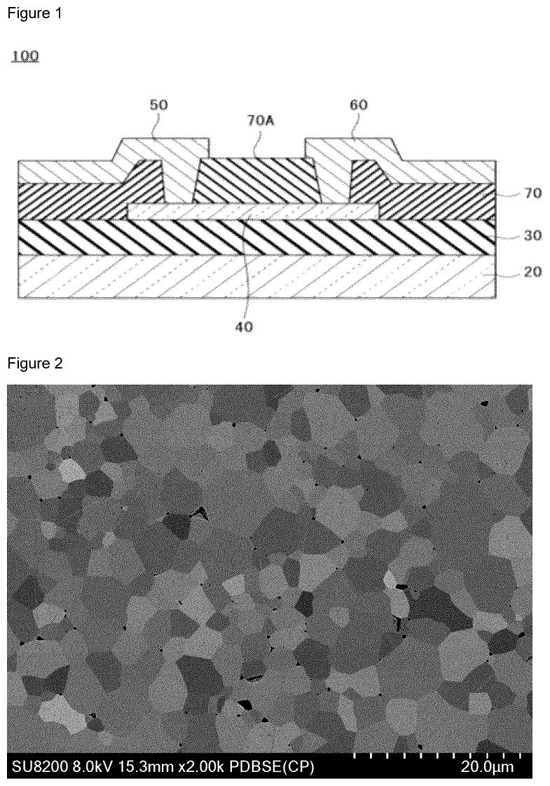

FIG. 1 is a schematic cross-sectional view of a thin film transistor according to one embodiment of the present invention.

As illustrated in FIG. 1, the thin film transistor 100 includes a silicon wafer 20, a gate insulating film 30, a semiconductor film 40, a source electrode 50, a drain electrode 60, an interlayer insulating film 70, and 70A.

The silicon wafer 20 is a gate electrode. The gate insulating film 30 is an insulating film that blocks conduction between the gate electrode and the semiconductor film 40, and is provided on the silicon wafer 20.

The semiconductor film 40 is a channel layer and is provided on the gate insulating film 30. The semiconductor film according to the present invention is used for the semiconductor film 40.

The source electrode 50 and the drain electrode 60 are conductive terminals for allowing the source current and the drain current to flow through the semiconductor film 40, and are provided to be in contact with adjacent to both ends of the semiconductor film 40.

The interlayer insulating film 70 is an insulating film that blocks conduction other than the contacting part between the source-electrode 50 and the drain-electrode 60 and the semiconductor film 40.

The interlayer insulating film 70A is an insulating film that blocks conduction other than the contacting part between the source-electrode 50 and the drain-electrode 60 and the semiconductor film 40. The interlayer insulating film 70A is also an insulating film that blocks conduction between the source-electrode 50 and the drain-electrode 60. The interlayer insulating film 70A is also a channel-layer protective layer.

The material for forming the drain electrode 60, the source electrode 50, and the gate electrode is not particularly limited, and a general used material can be arbitrarily selected. In the example of FIG. 1, a silicon wafer is used as a substrate, and a silicon wafer also serves as an electrode, but the electrode material is not limited to silicon.

For example, a transparent electrode such as ITO, indium oxide zinc (IZO), ZnO, and SnO₂, a metal electrode such as Al, Ag, Cu, Cr, Ni, Mo, Au, Ti, and Ta, or an alloyed metal electrode or a laminated electrode including these can be used.

In addition, in FIG. 1, a gate-electrode may be formed on a substrate such as glass.

The material for forming interlayer insulating film 70 and 70A is not also particularly limited, and a general used material can be selected. Specifically, for example, a compound such as SiO₂, SiNx, Al₂O₃, Ta₂O₅, TiO₂, MgO, ZrO₂, CeO₂, K₂O, Li₂O, Na₂O, Rb₂O, SC₂O₃, Y₂O₃, HfO₂, CaHfO₃, PbTiO₃, BaTa₂O₆, SrTiO₃, Sm₂O₃, and AlN can be used as a material for forming interlayer insulating film 70 and 70A.

Although the shape of the thin-film transistor according to the present aspect is not particularly limited, bottom-gate transistors, top-gate transistors, double-gate transistors, dual-gate transistors, back-channel etch transistors, or etch-stop transistors are preferred.

In transistor characteristics, On/Off properties are factors that determine the display performance of the display. When a thin film transistor is used as a switching device for liquid crystal, On/Off ratio is preferably 6-digit or more. For OLED, On current is critical for current driving, but On/Off ratio is preferably 6-digit or more as well.

In one embodiment, has an On/Off ratio of TFT is preferably 1×10⁶ or more.

On/Off ratio is more preferably 1×10⁶ to 1×10¹², more preferably 1×10⁷ to 10¹¹, and even more preferably 10⁸ to 10¹⁰. When On/Off ratio is 1×10⁶ or more, a liquid crystal display can be driven. When On/Off ratio is 1×10¹² or less, a large-contrast organic EL can be driven. When On/Off ratio is 1×10¹² or less, the off-state current can be set to be 10⁻¹¹ A or less, and when the thin film transistor is used as the transfer transistor or the reset transistor of CMOS image sensor, the retention time of the image can be increased or the sensitivity can be improved.

A method for measuring the On/Off ratio is described in detail in Examples.

In one embodiment, the mobility of TFT is preferably 5 cm²/V·s or greater, and more preferably 10 cm²/V·s or greater.

A method for measuring the linear mobility is described in detail in Examples.

The threshold-voltage (Vth) is preferably −3.0 to 3.0 V, more preferably −2.0 to 2.0 V, and even more preferably −1.0 to 1.0 V. When the threshold-voltage (Vth) is-3.0 V or higher, a high mobility TFT is obtained. When the threshold-voltage (Vth) is 3.0 V or lower, the off-state current is small, and an TFT having a large on-off ratio is obtained.

A method for measuring the threshold voltage (Vth) is described in detail in Examples.

The off-state current is preferably 1×10⁻¹⁰ A or less, more preferably 1×10⁻¹¹ A or less, and still more preferably 1×10⁻¹² A or less.

When the off-state current is 1×10⁻¹⁰ A or less, a large-contrast organic EL can be driven. In addition, when the TFT is used as a transfer transistor or a reset transistor for a CMOS image sensor, the retention time of an image can be lengthened, and sensitivity can be improved.

A method for measuring off-state current is described in detail in Examples.

The TFT according to this embodiment may be suitably used for electronic device such as solar cell, display device such as liquid crystal device, organic electroluminescence device, inorganic electroluminescence device, power semiconductor devices, and touch panel.

### EXAMPLES

The present invention is specifically described by way of Examples. The present invention is not limited to Examples.

### [Production of Sputtering Target]

### Example 1-1

0.01% by mass of tin oxide (manufactured by Kojundo Chemical Lab. Co., Ltd.) was added to 99.99% by mass of indium oxide (manufactured by Kojundo Chemical Lab. Co., Ltd.), and the mixture was pulverized using a planetary ball mill (Pulverisette 5, manufactured by FRITSCH, Germany). Zirconia beads were used as the grinding media, and it was treated at a rotational speed of 220 rpm for 4 hours.

The obtained powder was granulated, press-molded, and pressure-molded by CIP (cold isotropic pressing). The molded body was fired at 1450° C. for 28 hours to obtain an oxide sintered body. After cooling to room temperature in the furnace, it was ground polishing. A sputtering target having 4-inch-diameter and 5 mm thick was produced by bonding the polished oxide sinter to a backing plate. In Example 1-1, the sputtering target was free from cracks and the like, and thus it was possible to satisfactorily producing the sputtering target.

### Examples 1-2 to 1-5

As shown in Table 1, a sputtering target was produced in the same manner as in Example 1-1 except that the blending amount of indium oxide and tin oxide was changed. In the examples, the sputtering target was free from cracks and the like, and thus it was possible to satisfactorily producing the sputtering target.

### Comparative Examples 1-1 to 1-3

As shown in Table 1, a sputtering target was produced in the same manner as in Example 1-1, except that the blending amount of indium oxide and tin oxide was changed and a ball mill was used for mixing and grinding the raw materials. In a ball mill, a raw material and a zirconia ball were charged into a plastic container and rotated for 24 hours using a rotating roll.

For the sputtering targets prepared in the above-described Examples and Comparative Examples, the raw material composition, atomic (mol) ratio calculated from the composition, the number of tin atoms per 1 cm³, the relative density, and the bulk-resistance are shown in Table 1. The atomic ratio is a value from (In or Sn)/(In+Sn).

Further, using a CS200 manufactured by ULVAC, in an argon-gas atmosphere of 6% water (partial pressure), by applying a sputtering pressure 0.5 Pa, DC power 400 W (4-inch-diameter target), when it was sputtered continuously for two hours, the presence or absence of abnormal discharging was observed.

The results are shown in Table 1.

TABLE 1

| | Example1-1 | | Example1-2 | | Example1-3 | | Example1-4 | | Example1-5 | |
|---|---|---|---|---|---|---|---|---|---|---|
| | In₂O₃ | SnO₂ | In₂O₃ | SnO₂ | In₂O₃ | SnO₂ | In₂O₃ | SnO₂ | In₂O₃ | SnO₂ |
| Composition | 99.99 | 0.01 | 99.95 | 0.05 | 99.9 | 0.1 | 99.7 | 0.3 | 99.997 | 0.003 |
| (% by mass) | | | | | | | | | | |
| Atomic ratio | 0.999908 | 0.000092 | 0.999539 | 0.000461 | 0.999079 | 0.000921 | 0.997236 | 0.002764 | 0.999972 | 0.000028 |

| | | | | | |
|---|---|---|---|---|---|
| Number of tin atom | 6.5 × 10¹⁸ | 3.3 × 10¹⁹ | 6.5 × 10¹⁹ | 2.0 × 10²⁰ | 2.0 × 10¹⁸ |
| per 1 cm³ | | | | | |
| Producing method | Planetary ball mill | Planetary ball mill | Planetary ball mill | Planetary ball mill | Planetary ball mill |
| Relative density % | 99.1 | 99.2 | 99.4 | 99.5 | 98.9 |
| Bulk resistanse mΩcm | 4.5 | 2.8 | 1.4 | 0.54 | 8.70 |
| Abnormal discharge | Absence | Absence | Absence | Absence | Absence |
| during sputtering | | | | | |

| | Comparative | | Comparative | | Comparative | |
|---|---|---|---|---|---|---|
| | Example 1-1 | | Example 1-2 | | Example 1-3 | |
| | In₂O₃ | SnO₂ | In₂O₃ | SnO₂ | In₂O₃ | SnO₂ |
| Composition (% by mass) | 100 | 0 | 99.99 | 0.01 | 99.95 | 0.05 |
| Atomic ratio | 100 | 0 | 0.999908 | 0.000092 | 99.9539 | 0.0461 |

| | | | |
|---|---|---|---|
| Number of tin atom | 0 | 6.5 × 10¹⁸ | 3.3 × 10¹⁹ |
| per 1 cm³ | | | |
| Mixing and pulverizing method | Ball mill | Ball mill | Ball mill |
| Relative density % | 90.2 | 90.2 | 87.3 |
| Bulk resistanse mΩcm | 30 | 28 | 26 |
| Abnormal discharge | Presence | Presence | Presence |
| during sputtering | | | |

The number of tin atoms per 1 cm³ were calculated using tin density as 7.18 g/cm³ and chemical formula weight of indium oxide as 277.64. In both Examples and Comparative Examples, since the number of tin atoms per 1 cm³ is 1×10¹⁸ or more, it is considered that the electron concentration thereof is 10¹⁸ or more, and therefore it is expected that the film formed using the targeting becomes a conductive film. However, in the Example described later, a semiconductor film is obtained.

The relative density thereof is calculated by the formula “measured value×100/theoretical density (7.18 g/cm³)”.

The bulk-resistance (mΩcm) was measured on the basis of the four-probe method (JIS R 1637) using a resistivity meter Loresta (Loresta AX MCP-T370, manufactured by Mitsubishi Chemical). The measurement points were four points of the center of the sputtering target and the middle point between the four corners and the center, a total of five points, and the average value of the five points was the bulk resistance value.

From Table 1, it can be seen that the sputtering target produced using the planetary ball mill has a relative density of 99% or more, no abnormal discharge during sputtering is observed, and stable film formation can be performed.

FIG. 2 is a SEM photograph of a cross-section of a sputtering target (oxide sintered compact) produced in Example 1-1. From FIG. 2, the average crystalline particle size is 3.1 μm.

### [Production of Semiconductor Film and TFT]

### Examples 2-1 to 2-5

Semiconductor films (evaluating samples) and TFT semiconductor layers were produced using the sputtering targets produced in Examples 1-1 by the film-forming conditions (film-forming atmospheric gas partial pressure ratio) shown in Table 2.

### (A) Semiconductor Film (Sample for Evaluation)

### (1) Form of Oxide Film

An oxide film (film thickness 40 nm) was formed on a glass substrate (“ABC-G”, manufactured by Nippon Electric Glass) by the film forming conditions shown in Table 2.

The sputtering conditions except that shown in Table 2 are as described below.
Ultimate pressure: 5×10⁻⁵ Pa
Sputtering pressure: 0.5 Pa
Sputtering system: DC magnetron sputtering method
Sputtering power (W/cm²): 5.33 (400 W)
Duty: 100%
Distance between T (target) and S (substrate): 70 mm
Substrate Temperature: Room temperature

The obtained oxide film was analyzed by an inductive plasma atomic emission spectrometer (ICP-AES, manufactured by Shimadzu Corporation), and it was confirmed that atomic ratio of the metal atom of the oxide film was the same as atomic ratio of the metal atom of the sputtering target used for producing the film.

### (2) Crystallization (Annealing A)

The Substrate with the oxide film was heat-treated according to the conditions shown in Table 2. In Table 2, when the heating rate is “-”, it means that substrate is charged into the oven set to the heated temperature.

For the film after the treatment, the Hall effect measurement and the crystallinity (crystal or amorphous) of the film were evaluated.

### (3) Reduction Treatment (Annealing B)

The crystallized substrate of the above (2) was placed in an oven under a nitrogen-gas flow, heated from room temperature to 250° C. in 3 minutes, and held at 250° C. for 5 minutes. After that, it was cooled to 100° C. or less, was taken out from the furnace.

The film after the treatment was measured for the Hall effect.

### (4) Stabilization (Annealing C)

After (3) above, heat treatment was performed again at the temperature and time shown in Table 2 under atmosphere.

For the film after the treatment, the Hall effect and the concentration of the hydrogen atom (H) measured by secondary ion mass spectrometry were measured.

### (B) Production of TFT

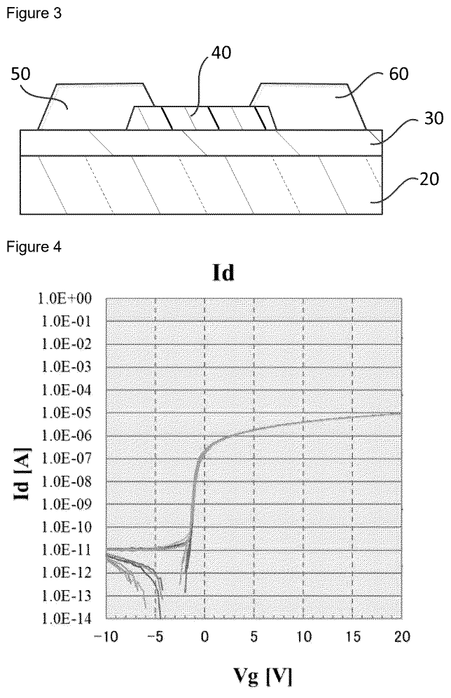

TFT shown in FIG. 3 was produced.

### (1) Form of Oxide (Amorphous) Film

A silicon wafer 20 (gate electrode) with a SiO₂ thermal oxide film (gate insulating film 30) was used as a substrate. An amorphous film 40 having a 40 nm thickness was formed on SiO₂ thermal oxide film by sputtering through a metal mask using the sputtering target produced in Example 1-1 under the same film formation conditions as in (A) (1) above.

### (2) Formation of Source Electrode and Drain Electrode

Next, a titanium electrode as the source electrode 50 and the drain electrode 60 was formed by sputtering using a titanium metal target through a metal mask used for forming the contact hole shapes for the source electrode 50 and the drain electrode 60, thereby producing a TFT.

### (3) Crystallization (Annealing A)

TFT obtained in (2) above was heat-treated under the same conditions (Table 2) as in (A) above.

### (4) Reduction Treatment (Annealing B)

The crystallized TFT of the above (3) was heat-treated under the same conditions (Table 2) as the above (A) semiconductor film (sample for evaluation). That is, placed in a furnace under a nitrogen stream, the temperature was raised in 3 minutes from room temperature to 250° C. and held at 250° C. for 5 minutes. After that, it was cooled to 100° C. or less, was taken out from the furnace.

### (5) Stabilization (Annealing C)

After the above (4), heat treatment was performed again under the same conditions (Table 2) as the above (A) semiconductor film (sample for evaluation).

### [Characterization Evaluation]

Samples for evaluation and TFTs were evaluated as follows. The results are shown in Table 2. In the tables, “X.XXE+YY” means “X.XX×10^{+YY}”. For example, “1E-12” is “1×10⁻¹²”.

### (Hall Effect Measurement)

Each sample for evaluation after annealing A, B, and C was evaluated. Metallic indium (In) was soldered to the four corners of the film-attached substrate to a size of about 2 mm×2 mm or less to prepare a Hall-effect measuring sample.

The sample for Hall effect measuring was set in a Hall effect and resistivity measuring device (ResiTest8300 type, manufactured by Toyo Technica) to evaluate the Hall effect at room temperature, to determine the carrier concentration and mobility.

### (Crystallinity of Film)

The evaluation sample before and after the annealing A was evaluated. The crystallinity of the oxide films was evaluated by X-ray diffractometry (XRD). When no peak was observed in XRD measurement, it was judged as “amorphous”, and when a peak was observed in XRD measurement, it was judged as “crystalline”. When a broad micropattern was observed instead of a clear peak, it was regarded as a “microcrystal”.

When the X-ray diffractometry spectrum obtained by measuring XRD was evaluated, it was confirmed that the crystal was a bixbyite-structured crystal.

### (Etching Characteristics)

The sample for evaluation before annealing A was evaluated. The etching characteristics of the oxide film were evaluated at the taper angle. Specifically, a resist film patterned in the form of 1 mm lines and spaces was formed on the substrate having the oxide film formed thereon by a photolithography process. In a 4% of oxalic acid aqueous solution, the etching time was set to 1.5 times the just etching time, the cross-section of the etching surface was observed SEM, and the etching angle was measured.

### (Concentration of Hydrogen Atom)

The evaluation sample after annealing C was evaluated. By a dynamic secondary ion mass spectrometer (D-SIMS, manufactured by ULVAC-PHI, INC.), the evaluation sample was measured under Cs ion source of 1 kV, the primary ion current of 100 nA, and the chamber vacuum degree of 5×10⁻¹⁰ torr as measured conditions. The secondary ion intensity of H at each depth obtained by the dynamic secondary ion mass spectrometer was integrated by the film thickness in order to eliminate the effect of the semiconductor film interface, and the intensity was normalized using a hydrogen concentration and an In—O thin film having a known film thickness to quantify the hydrogen concentration, and the average value of the obtained value was defined as the concentration of the hydrogen atom.

### (Characterization Evaluation of TFT)

Linear mobility, threshold-voltage (Vth), On/Off ratio, and off-state current were evaluated for TFT after annealing A and after annealing C.

Linear mobility was obtained from the transfer property of 0.1 V applied to the drain-voltage. Specifically, the transfer property Id-Vg was plotted, the transconductance (Gm) of each Vg was calculated, and the linear mobility was derived by formula of the linear domain. Note that, Gm is represented by a (Id)/a (Vg) and Vg is applied to −15 to 25 V, and the maximum mobility in the region is defined as the linear mobility. Id is a current between the source and drain electrodes, and Vg is a gate voltage when a voltage Vd is applied between the source and drain electrodes. Threshold-voltage (Vth) was defined as Vg at Id=10⁻⁹ A from the plot of the transfer property.

On/Off ratio was calculated by the ratio [on-state current value/off-state current value], where the Id value was used as the off-state current value at Vg=−10 V and the Id value was used as the on-state current value at Vg=20 V.

### (Characterization Evaluation of Fast-Response TFT)

TFT after annealing C was evaluated.

The field-effect mobility u in the linear domain is obtained from the transfer properties when applied 0.1 V to the drain-voltage. Specifically, the transfer property Id-Vg was plotted, the transconductance (Gm) of each Vg was calculated, and the field-effect mobility was derived by the formula of the linear domain. Gm is represented by a (Id)/a (Vg). Vg is applied from-15 to 20 V and the maximum mobility is defined as the field-effect mobility. Id is a current between the source and drain electrodes, and Vg is a gate voltage when a voltage Vd is applied between the source and drain electrodes.

The field-effect mobility of Vg=Vth+5 (V) was obtained from a graph of Vg and u obtained by the method of the field-effect mobility in the linear domain. The average field-effect mobility of Vg=Vth (V) to Vth+20 (V) was obtained from the following formula.

$$Average mobility = {\int }_{Vth}^{Vth + 20} μ dVg / 20$$

A TFT in which the field-effect mobility of Vg=Vth+5 (V) is 10 cm²/V·s or greater and the average field-effect mobility of Vg=Vth (V) to Vth+20 (V) is 50% or greater of the maximal field-effect mobility in the region can be referred to as a fast-response TFT.

TABLE 2

| | | Example 2-1 | | Example 2-2 | | Example 2-3 | Example 2-4 | Example 2-5 |
|---|---|---|---|---|---|---|---|---|
| Sputtering gas | [O2]/([O2] + [H2] + [H2O] + [Ar]) | 0 | | 0 | | 0 | 0 | 0 |
| composition | [H2]/([O2] + [H2] + [H2O] + [Ar]) | 0 | | 0 | | 0 | 1 | 2 |
| (Partial pressure: %) | [H2O]/([O2] + [H2] + [H2O] + [Ar]) | 6 | | 6 | | 1 | 6 | 6 |
| | [Ar]/([O2] + [H2] + [H2O] + [Ar]) | 94 | | 94 | | 99 | 93 | 92 |
| Evaluation | Crystallinity(XRD) | Amorphous | | Amorphous | | Amorphous | Amorphous | Amorphous |
| before annealing A | Etching characteristic: Taper angle (°) | 72 | | 80 | | 76 | 78 | 75 |
| Conditions of | First stage: Temperature (°C.) (time) | 250 | (60 min) | 350 | (60 min) | 350 (60 min) | 250 (60 min) | 350 (60 min) |
| annealing A | Rate of temperarure increase (°C./min) | — | | 10 | | 10 | — | 10 |
| | Second stage: Temperature (°C.) (time) | 300° C. | (60 min) | — | | — | 300 (60 min) | — |
| | Atmospheric gas | Atmosphere | | Atmosphere | | Atmosphere | Atmosphere | Atmosphere |
| Evaluation | Crystallinity (XRD) | Crystalline | | Crystalline | | Crystalline | Crystalline | Crystalline |
| after annealing A | Hall measurement: | <1E+17 | | <1E+17 | | <1E+17 | <1E+17 | <1E+17 |
| | Carrier concentration (cm−3) | | | | | | | |
| | Hall measurement: Mobility (cm2/V · s) | — | | — | | — | — | — |
| Conditions of | Annealing temperature (C) (time) | 250° C. (Temperature increase in 3 min: 5 min) | | | | | | |
| annealing B | Atmospheric gas | N2 | | | | | | |
| Evaluation | Hall measurement: | 1.26E+19 | | 1.63E+19 | | 1.81E+19 | 1.68E+19 | 1.9E+19 |
| after annealing B | Carrier concentration (cm−3) | | | | | | | |
| | Hall measurement: Mobility (cm2/V · s) | 35.5 | | 38.1 | | 47.6 | 46.7 | 42.7 |
| Conditions of | Annealing temperature (°C.) (time) | 250° C. | (60 min) | 350° C. | (60 min) | 350 (60 min) | 350 (60 min) | 300 (60 min) |

| | | | | | | |
|---|---|---|---|---|---|---|
| annealing C | Atmospheric gas | Atmosphere | Atmosphere | Atmosphere | Atmosphere | Atmosphere |
| Evaluation | Hall measurement: | 6.06E+17 | <1E+17 | 7.39E+17 | 2.19E+18 | 9.72E+17 |
| after Annealing C | Carrier concentration (cm−3) | | | | | |
| | Hall measurement: Mobility (cm2/V · s) | 13.7 | — | 19.4 | 31.1 | 18.1 |
| | H concentration (atoms/cc) | 6.4E+20 | 4.7E+20 | 1.8E+20 | 7.4E+20 | 7.9E+20 |
| TFT characteristics | Linear mobility (cm2/V · s) | 35 | 37 | 40 | 36 | 33 |
| after annealing A | Vth (V) | −2 | −1 | −3 | −3 | −2 |
| | on/off ratio | 7 | 7 | 8 | 7 | 7 |
| | Off-state current value (A) | 1E−12 | 1E−12 | 1E−13 | 1E−12 | 1E−12 |
| TFT characteristics | Linear mobility (cm2/V · s) | 35 | 37 | 40 | 35 | 37 |
| after annealing C | Vth (V) | −1 | −1 | −1 | 0 | 0 |
| | on/off ratio | 7 | 7 | 7 | 7 | 7 |
| | Off-state current value (A) | 1E−12 | 1E−12 | 1E−12 | 1E−12 | 1E−12 |
| Fast response | Mobility of Vth + 5 V (cm2/V · s) | 22 | 25 | 27 | 25 | 28 |
| TFT characteristics | Average mobility ratio (%) | 74 | 78 | 72 | 70 | 75 |

### Examples 3-1 to 3-3

Semiconductor films (samples for evaluation) and TFT semiconductor layers were produced and evaluated in the same manner as in Example 2-1, except that the sputtering target produced in Example 1-2 was used under the film-forming conditions shown in Table 3. The results are shown in Table 3.

TABLE 3

| | | Example 3-1 | Example 3-2 | Example 3-3 | |
|---|---|---|---|---|---|
| Sputtering gas | [O2]/([O2] + [H2] + [H2O] + [Ar]) | 0 | 0 | 0 | |
| composition | [H2]/([O2] + [H2] + [H2O] + [Ar]) | 0 | 1 | 2 | |
| (Partial pressure: %) | [H2O]/([O2] + [H2] + [H2O] + [Ar]) | 6 | 6 | 6 | |
| | [Ar]/([O2] + [H2] + [H2O] + [Ar]) | 94 | 93 | 92 | |
| Evaluation | Crystallinity(XRD) | Amorphous | Amorphous | Amorphous | |
| before annealing A | Etching characteristic: Taper angle (°) | 77 | 76 | 77 | |
| Conditions of | First stage: Temperature (° C.) (time) | 300 (60 min) | 250 (60 min) | 350 | (60 min) |
| annealing A | Rate of temperarure increase (° C./min) | — | — | 10 | |
| | Second stage: Temperature (° C.) (time) | — | 300 (60 min) | — | |
| | Atmospheric gas | Atmosphere | Atmosphere | Atmosphere | |
| Evaluation | Crystallinity (XRD) | Crystalline | Crystalline | Crystalline | |
| after annealing A | Hall measurement: | <1E+17 | 4.25E+18 | <1E+17 | |
| | Carrier concentration (cm−3) | | | | |
| | Hall measurement: Mobility (cm2/V · s) | — | 32.1 | — | |
| Conditions of | Annealing temperature (° C.) (time) | 250° C. (Temperature increase in 3 min:5 min) | | | |
| annealing B | Atmospheric gas | N2 | | | |
| Evaluation | Hall measurement: | 2.37E+19 | 2.58E+19 | 2.13E+19 | |
| after annealing B | Carrier concentration (cm−3) | | | | |
| | Hall measurement: Mobility (cm2/V · s) | 40.6 | 50.1 | 48.2 | |
| Conditions of | Annealing temperature (° C.) (time) | 350 (60 min) | 350 (60 min) | 300° C. | (60 min) |
| annealing C | Atmospheric gas | Atmosphere | Atmosphere | Atmosphere | |
| Evaluation | Hall measurement: | 7.89E+17 | 4.62E+18 | 1.02E+18 | |
| after Annealing C | Carrier concentration (cm−3) | | | | |

| | Hall measurement: Mobility (cm2/V · s) | 21.1 | 36.6 | 22.4 |
|---|---|---|---|---|
| | H concentration (atoms/cc) | 6.5E+20 | 7.7E+20 | 8.0E+20 |
| TFT characteristics | Linear mobility (cm2/V · s) | 35 | 34 | 37 |
| after annealing A | Vth (V) | −2 | −3 | 0 |
| | on/off ratio | 6 | 6 | 8 |
| | Off-state current value (A) | 1E−11 | 1E−11 | 1E−13 |
| TFT characteristics | Linear mobility (cm2/V · s) | 34 | 35 | 35 |
| after annealing C | Vth (V) | 0 | 0 | 0 |
| | on/off ratio | 7 | 7 | 7 |
| | Off-state current value (A) | 1E−12 | 1E−12 | 1E−12 |
| Fast response | Mobility of Vth + 5 V (cm2/V · s) | 25 | 23 | 21 |
| TFT characteristics | Average mobility ratio (%) | 72 | 72 | 70 |

### Examples 4-1 to 4-3

Semiconductor films (samples for evaluation) and TFT semiconductor layers were produced and evaluated in the same manner as in Example 2-1, except that the sputtering target produced in Example 1-3 was used under the film-forming conditions shown in Table 4. In Example 4-3, the pulse DC sputtering method was used, and the pulse frequency 100 kHz and the Duty was set to 50%. The results are shown in Table 4.

TABLE 4

| | | Example 4-1 | Example 4-2 | Example 4-3 * |
|---|---|---|---|---|
| Sputtering gas | [O2]/([O2] + [H2] + [H2O] + [Ar]) | 0 | 0 | 0 |
| composition | [H2]/([O2] + [H2] + [H2O] + [Ar]) | 0 | 2 | 2 |
| (Partial pressure: %) | [H2O]/([O2] + [H2] + [H2O] + [Ar]) | 6 | 6 | 6 |
| | [Ar]/([O2] + [H2] + [H2O] + [Ar]) | 94 | 92 | 92 |
| Evaluation | Crystallinity(XRD) | Amorphous | Amorphous | Amorphous |
| before annealing A | Etching characteristic: Taper angle (°) | 76 | 75 | 77 |
| Conditions of | First stage: Temperature (° C.) (time) | 250 (60 min) | 300 (60 min) | 250 (60 min) |
| annealing A | Rate of temperarure increase (° C./min) | — | — | — |
| | Second stage: Temperature (° C.) (time) | 300 (60 min) | — | — |
| | Atmospheric gas | Atmosphere | Atmosphere | Atmosphere |
| Evaluation | Crystallinity (XRD) | Crystalline | Crystalline | Crystalline |
| after annealing A | Hall measurement: | <1E+17 | <1E+17 | 6.71E+17 |
| | Carrier concentration (cm−3) | | | |
| | Hall measurement: Mobility (cm2/V · s) | — | — | 19.6 |
| Conditions of | Annealing temperature (° C.) (time) | 250° C. (Temperature increase in 3 min:5 min) | | |
| annealing B | Atmospheric gas | N2 | | |
| Evaluation | Hall measurement: | 1.28E+19 | 2.37E+19 | 2.18E+19 |
| after annealing B | Carrier concentration (cm−3) | | | |
| | Hall measurement: Mobility (cm2/V · s) | 33.9 | 40.6 | 48.1 |
| Conditions of | Annealing temperature (° C.) (time) | 350 (60 min) | 350 (60 min) | 350 (60 min) |
| annealing C | Atmospheric gas | Atmosphere | Atmosphere | Atmosphere |
| Evaluation | Hall measurement: | <1E+17 | 7.89E+17 | 2.83E+18 |
| after Annealing C | Carrier concentration (cm−3) | | | |
| | Hall measurement: Mobility (cm2/V · s) | — | 21.1 | 6.09 |
| | H concentration (atoms/cc) | 6.7E+20 | 7.9E+20 | 8.1E+20 |
| TFT characteristics | Linear mobility (cm2/V · s) | 30 | 35 | 40 |
| after annealing A | Vth (V) | −4 | −2 | −5 |
| | on/off ratio | 6 | 6 | 6 |
| | Off-state current value (A) | 1E−11 | 1E−11 | 1E−11 |
| TFT characteristics | Linear mobility (cm2/V · s) | 30 | 33 | 30 |
| after annealing C | Vth (V) | −1 | −1 | 0 |
| | on/off ratio | 6 | 6 | 6 |
| | Off-state current value (A) | 1E−11 | 1E−11 | 1E−11 |
| Fast response | Mobility of Vth + 5 V (cm2/V · s) | 18 | 19 | 21 |
| TFT characteristics | Average mobility ratio (%) | 69 | 68 | 75 |

* Example 4-3: Pulsed DC Sputtering

### Examples 5-1 to 5-3

Semiconductor films (samples for evaluation) and TFT semiconductor layers were produced and evaluated in the same manner as in Example 2-1, except that the sputtering target produced in Examples 1˜4 was used under the film-forming conditions shown in Table 5. In Example 5-3, the pulse DC sputtering method was used, and the pulse frequency was set to 100 kHz and Duty was set to 50%. The results are shown in Table 5.

TABLE 5

| | | Example 5-1 | Example 5-2 | Example 5-3 * |
|---|---|---|---|---|
| Sputtering gas | [O2]/([O2] + [H2] + [H2O] + [Ar]) | 0 | 0 | 0 |
| composition | [H2]/([O2] + [H2] + [H2O] + [Ar]) | 0 | 2 | 2 |
| (Partial pressure: %) | [H2O]/([O2] + [H2] + [H2O] + [Ar]) | 6 | 6 | 6 |
| | [Ar]/([O2] + [H2] + [H2O] + [Ar]) | 94 | 92 | 92 |
| Evaluation | Crystallinity(XRD) | Amorphous | Amorphous | Amorphous |
| before annealing A | Etching characteristic: Taper angle (°) | 80 | 78 | 78 |
| Conditions of | First stage: Temperature (° C.) (time) | 250 (60 min) | 300 (60 min) | 300 (60 min) |
| annealing A | Rate of temperarure increase (° C./min) | — | — | — |
| | Second stage: Temperature (° C.) (time) | 300 (60 min) | — | — |
| | Atmospheric gas | Atmosphere | Atmosphere | Atmosphere |
| Evaluation | Crystallinity (XRD) | Crystalline | Crystalline | Crystalline |
| after annealing A | Hall measurement: | <1E+17 | 5.57E+17 | 2.77E+18 |
| | Carrier concentration (cm−3) | | | |
| | Hall measurement: Mobility (cm2/V · s) | — | 15.8 | 16.4 |
| Conditions of | Annealing temperature (° C.) (time) | 250° C. (Temperature increase in 3 min:5 min) | | |
| annealing B | Atmospheric gas | N2 | | |
| Evaluation | Hall measurement: | 8.4E+16 | 1.91E+19 | 3.57E+19 |
| after annealing B | Carrier concentration (cm−3) | | | |
| | Hall measurement: Mobility (cm2/V · s) | 3.51 | 33.4 | 37.1 |
| Conditions of | Annealing temperature (° C.) (time) | 350 (60 min) | 350 (60 min) | 350 (60 min) |
| annealing C | Atmospheric gas | Atmosphere | Atmosphere | Atmosphere |
| Evaluation | Hall measurement: | <1E+17 | 1.4E+17 | 3.18E+18 |
| after Annealing C | Carrier concentration (cm−3) | | | |
| | Hall measurement: Mobility (cm2/V · s) | — | 38.7 | 18.8 |
| | H concentration (atoms/cc) | 6.9E+20 | 8.0E+20 | 8.3E+20 |
| TFT characteristics | Linear mobility (cm2/V · s) | 28 | 30 | 31 |
| after annealing A | Vth (V) | −5 | −5 | −3 |
| | on/off ratio | 6 | 6 | 7 |
| | Off-state current value (A) | 1E−11 | 1E−11 | 1E−12 |
| TFT characteristics | Linear mobility (cm2/V · s) | 25 | 25 | 25 |
| after annealing C | Vth (V) | −4 | −2 | −2 |
| | on/off ratio | 6 | 6 | 6 |
| | Off-state current value (A) | 1E−12 | 1E−12 | 1E−12 |
| Fast response | Mobility of Vth + 5 V (cm2/V · s) | 10 | 14 | 14 |
| TFT characteristics | Average mobility ratio (%) | 58 | 68 | 69 |

* Example 5-3: Pulsed DC sputtering

### Examples 6-1 to 6-3

Semiconductor films (samples for evaluation) and TFT semiconductor layers were produced and evaluated in the same manner as in Example 2-1, except that the sputtering target produced in Examples 1-5 was used under the film-forming conditions shown in Table 6. The results are shown in Table 6.

TABLE 6

| | | Example 6-1 | Example 6-2 | Example 6-3 |
|---|---|---|---|---|
| Sputtering gas | [O2]/([O2] + [H2] + [H2O] + [Ar]) | 0 | 0 | 0 |
| composition | [H2]/([O2] + [H2] + [H2O] + [Ar]) | 2 | 2 | 2 |
| (Partial pressure: %) | [H2O]/([O2] + [H2] + [H2O] + [Ar]) | 6 | 6 | 6 |
| | [Ar]/([O2] + [H2] + [H2O] + [Ar]) | 92 | 92 | 92 |
| Evaluation | Crystallinity(XRD) | Amorphous | Amorphous | Amorphous |
| before annealing A | Etching characteristic: Taper angle (°) | 82 | 81 | 81 |
| Conditions of | First stage: Temperature (° C.) (time) | 300 (60 min) | 350 (60 min) | 400 (60 min) |
| annealing A | Rate of temperarure increase (° C./min) | — | 10 | 10 |
| | Second stage: Temperature (° C.) (time) | — | — | — |
| | Atmospheric gas | Atmosphere | Atmosphere | Atmosphere |
| Evaluation | Crystallinity (XRD) | Crystalline | Crystalline | Crystalline |
| after annealing A | Hall measurement: | <1E+17 | <1E+17 | <1E+17 |
| | Carrier concentration (cm−3) | | | |
| | Hall measurement: Mobility (cm2/V · s) | — | — | — |
| Conditions of | Annealing temperature (° C.) (time) | 250° C. (Temperature increase in 3 min:5 min) | | |
| annealing B | Atmospheric gas | N2 | | |
| Evaluation | Hall measurement: | 4.41E+18 | 1.31E+19 | 1.09E+19 |
| after annealing B | Carrier concentration (cm−3) | | | |
| | Hall measurement: Mobility (cm2/V · s) | 26.3 | 34.1 | 32.3 |
| Conditions of | Annealing temperature (° C.) (time) | 350 (60 min) | 350 (60 min) | 350 (60 min) |
| annealing C | Atmospheric gas | Atmosphere | Atmosphere | Atmosphere |
| Evaluation | Hall measurement: | <1E+17 | <1E+17 | <1E+17 |
| after Annealing C | Carrier concentration (cm−3) | | | |
| | Hall measurement: Mobility (cm2/V · s) | — | — | — |
| | H concentration (atoms/cc) | 8.6E+20 | 7.9E+20 | 6.3E+20 |
| TFT characteristics | Linear mobility (cm2/V · s) | 35 | 36 | 35 |
| after annealing A | Vth (V) | −1 | 0 | 1 |
| | on/off ratio | 7 | 8 | 8 |
| | Off-state current value (A) | 1E−12 | 1E−13 | 1E−13 |
| TFT characteristics | Linear mobility (cm2/V · s) | 35 | 35 | 35 |
| after annealing C | Vth (V) | −1 | 0 | 1 |
| | on/off ratio | 7 | 7 | 7 |
| | Off-state current value (A) | 1E−12 | 1E−12 | 1E−12 |
| Fast response | Mobility of Vth + 5 V (cm2/V · s) | 23 | 25 | 25 |
| TFT characteristics | Average mobility ratio (%) | 71 | 73 | 73 |

### Comparative Examples 2-1 to 2-3

Semiconductor films (samples for evaluation) and TFT semiconductor layers were produced and evaluated in the same manner as in Example 2-1, except that the sputtering target produced in Comparative Example 1-1 was used under the film-forming conditions shown in Table 7. The results are shown in Table 7.

As in Comparative Example 2-1, when a high-purity indium oxide target was used, the linear mobility of TFT characteristic was 30 cm²/V. after annealing A at 300° C., but the linear mobility decreased to 10 cm²/V·s after annealing at 350° C. which was a stabilization treatment (annealing C).

TABLE 7

| | | Comparative | Comparative | Comparative |
|---|---|---|---|---|
| | | Example 2-1 | Exapmple 2-2 | Example 2-3 |
| Sputtering gas | [O2]/([O2] + [H2] + [H2O] + [Ar]) | 0 | 0 | 0 |
| composition | [H2]/([O2] + [H2] + [H2O] + [Ar]) | 0 | 0 | 0 |
| (Partial pressure: %) | [H2O]/([O2] + [H2] + [H2O] + [Ar]) | 6 | 3 | 1 |
| | [Ar]/([O2] + [H2] + [H2O] + [Ar]) | 94 | 97 | 99 |
| Evaluation | Crystallinity(XRD) | Amorphous | Amorphous | Microcrystal |
| before annealing A | Etching characteristic: Taper angle (°) | 77 | 75 | Residue |
| | | | | generation |
| Conditions of | First stage: Temperature (° C.) (time) | 270 (60 min) | 300 (60 min) | 300 (60 min) |
| annealing A | Rate of temperarure increase (° C./min) | 50 | 50 | 50 |
| | Second stage: Temperature (° C.) (time) | 300 (60 min) | 350 (60 min) | 350 (60 min) |
| | Atmospheric gas | Atmosphere | Atmosphere | Atmosphere |
| Evaluation | Crystallinity (XRD) | Crystalline | Crystalline | Crystalline |
| after annealing A | Hall measurement: | 8.72E+17 | 6.1E+16 | 9.00E+18 |
| | Carrier concentration (cm−3) | | | |
| | Hall measurement: Mobility (cm2/V · s) | 14.8 | 4.1 | 7.12 |
| Conditions of | Annealing temperature (° C.) (time) | 250° C. (Temperature increase in 3 min:5 min) | | |
| annealing B | Atmospheric gas | N2 | | |
| Evaluation | Hall measurement: | 4.35E+18 | 2.72E+19 | 3.01E+19 |
| after annealing B | Carrier concentration (cm−3) | | | |
| | Hall measurement: Mobility (cm2/V · s) | 43.3 | 54.5 | 44.1 |
| Conditions of | Annealing temperature (° C.) (time) | 350 (60 min) | 350 (60 min) | 300 (60 min) |
| annealing C | Atmospheric gas | Atmosphere | Atmosphere | Atmosphere |
| Evaluation | Hall measurement: | 7.54E+16 | 1.14E+17 | 7.34E+18 |
| after Annealing C | Carrier concentration (cm−3) | | | |
| | Hall measurement: Mobility (cm2/V · s) | 4.2 | 15.4 | 9.6 |
| | H concentration (atoms/cc) | 6.2E+20 | 2.9E+20 | 1.1E+20 |
| TFT characteristics | Linear mobility (cm2/V · s) | 30 | 14 | Conduction |
| after annealing A | Vth (V) | −1 | −1 | — |
| | on/off ratio | 7 | 6 | — |
| | Off-state current value (A) | 1E−12 | 1E−12 | — |
| TFT characteristics | Linear mobility (cm2/V · s) | 10 | 10 | Conduction |
| after annealing C | Vth (V) | −3 | −4 | — |
| | on/off ratio | 5 | 4 | — |
| | Off-state current value (A) | 1E−11 | 1E−11 | — |
| Fast response | Mobility of Vth + 5 V (cm2/V · s) | — | — | — |
| TFT characteristics | Average mobility ratio (%) | — | — | — |

### Comparative Examples 3-1 to 3-4

Semiconductor films (samples for evaluation) and TFT semiconductor layers were produced and evaluated in the same manner as in Example 2-1, except that the sputtering target produced in Example 1-1 was used under the film-forming conditions shown in Table 8. The results are shown in Table 8.

TABLE 8

| | | Comparative | | Comparative | | Comparative | | Comparative | |
|---|---|---|---|---|---|---|---|---|---|
| | | Example 3-1 | | Example 3-2 | | Example 3-3 | | Example 3-4 | |
| Sputtering gas | [O2]/([O2] + [H2] + [H2O] + [Ar]) | 10 | | 10 | | 0 | | 0.5 | |
| composition | [H2]/([O2] + [H2] + [H2O] + [Ar]) | 0 | | 0 | | 0 | | 0 | |
| (Partial pressure: %) | [H2O]/([O2] + [H2] + [H2O] + [Ar]) | 0 | | 0 | | 0.1 | | 0.1 | |
| | [Ar]/([O2] + [H2] + [H2O] + [Ar]) | 90 | | 90 | | 99.9 | | 99.4 | |
| Evaluation | Crystallinity(XRD) | Crystalline | | Crystalline | | Microcrystal | | Microcrystal | |
| before annealing A | Etching characteristic: Taper angle (°) | Residue | | Residue | | Residue | | Residue | |
| | | generation | | generation | | generation | | generation | |
| Conditions of | First stage: Temperature (° C.) (time) | 275 | (60 min) | 300 | (60 min) | 300 | (60 min) | 350 | (60 min) |
| annealing A | Rate of temperarure increase (° C./min) | — | | — | | — | | 10 | |
| | Second stage: Temperature (° C.) (time) | 350 | (60 min) | — | | — | | — | |
| | Atmospheric gas | Atmosphere | | Atmosphere | | Atmosphere | | Atmosphere | |
| Evaluation | Crystallinity (XRD) | Crystalline | | Crystalline | | Crystalline | | Crystalline | |
| after annealing A | Hall measurement: | 2.52E+18 | | 1.29E+18 | | 8.84E+19 | | 3.47E+18 | |
| | Carrier concentration (cm−3) | | | | | | | | |
| | Hall measurement: Mobility (cm2/V · s) | 6.98 | | 6.36 | | 59.8 | | 8.37 | |
| Conditions of | Annealing temperature (° C.) (time) | 250° C. (Temperature increase in 3 min:5 min) | | | | | | | |
| annealing B | Atmospheric gas | N2 | | | | | | | |
| Evaluation | Hall measurement: | 4.38E+19 | | 6.27E+18 | | 1.41E+20 | | 4.24E+19 | |
| after annealing B | Carrier concentration (cm−3) | | | | | | | | |
| | Hall measurement: Mobility (cm2/V · s) | 36.7 | | 40.7 | | 71.9 | | 66.1 | |
| Conditions of | Annealing temperature (° C.) (time) | 300° C. | (60 min) | 300° C. | (60 min) | 300° C. | (60 min) | 300° C. | (60 min) |
| annealing C | Atmospheric gas | Atmosphere | | Atmosphere | | Atmosphere | | Atmosphere | |
| Evaluation | Hall measurement: | 1.92E+18 | | 1.59E+18 | | 8.07E+19 | | 2.4E+18 | |
| after Annealing C | Carrier concentration (cm−3) | | | | | | | | |

| | Hall measurement: Mobility (cm2/V · s) | 6.61 | 5.31 | 58.9 | 8.09 |
|---|---|---|---|---|---|
| | H concentration (atoms/cc) | 4.5E+19 | 6.7E+19 | 7.7E+19 | 8.5E+19 |
| TFT characteristics | Linear mobility (cm2/V · s) | Conduction | Conduction | Conduction | Conduction |
| after annealing A | Vth (V) | — | — | — | — |
| | on/off ratio | — | — | — | — |
| | Off-state current value (A) | — | — | — | — |
| TFT characteristics | Linear mobility (cm2/V · s) | Conduction | Conduction | Conduction | Conduction |
| after annealing C | Vth (V) | — | — | — | — |
| | on/off ratio | — | — | — | — |
| | Off-state current value (A) | — | — | — | — |
| Fast response | Mobility of Vth + 5 V (cm2/V · s) | — | — | — | — |
| TFT characteristics | Average mobility ratio (%) | — | — | — | — |

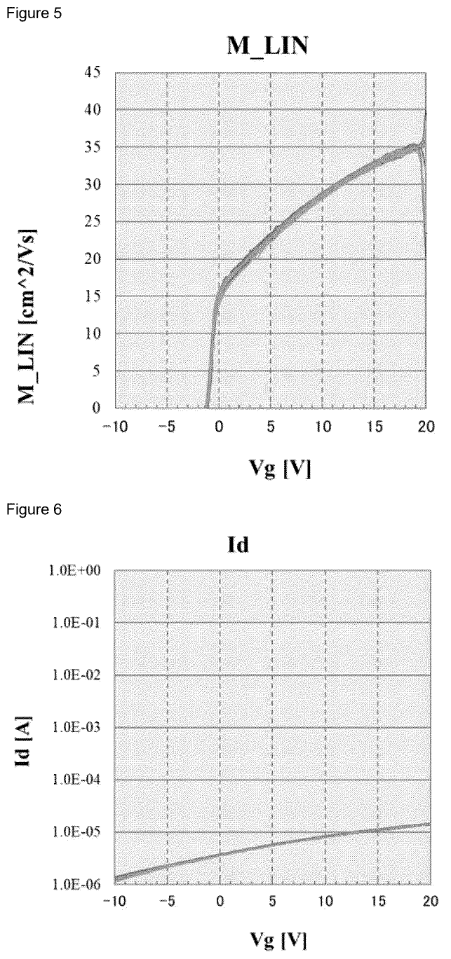

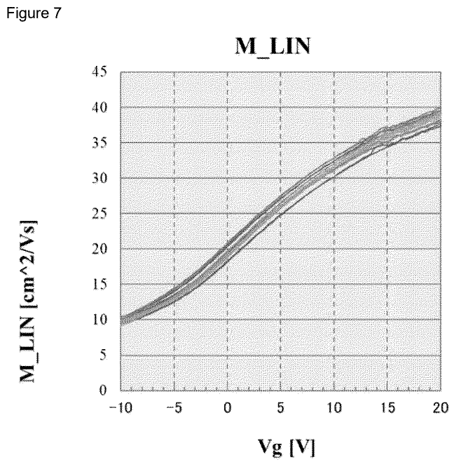

FIG. 4 is a transfer curve of TFT produced in Example 2-1. FIG. 5 is a graph of Vg and u in TFT produced in Example 2-1. FIG. 6 is a transfer curve of TFT produced in Comparative Example 3-1. FIG. 7 is a graph of Vg and u in TFT produced in Comparative Example 3-1.

From FIGS. 4 and 5, it can be seen that TFT where the partial pressure of water in the sputtering gas is set to 6% exhibits good performance. On the other hand, from FIGS. 6 and 7, it can be seen that when the film is formed in the absence of the gas supplying the hydrogen atom as in the comparative examples, the characteristics of the obtained TFT are inferior even when the film is sputtered by coexisting oxygen.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1. (canceled)

2. A semiconductor film comprising a solid phase crystallized product of tin and hydrogen-doped indium oxide, wherein the amount of tin atom (Sn) based on the total amount of indium atom (In) and tin atom (Sn) [Sn/(In+Sn): molar ratio] in the solid phase crystallized product is 0.000005 to 0.008, and the concentration of the hydrogen atom (H) measured by the secondary ion mass spectrometry is 0.5×10²⁰ to 50×10²⁰ atoms/cc.

3. The semiconductor film according to claim 2, wherein the cross-section thereof is a tapered shape.

4. A method for producing the semiconductor film according to claim 2, comprising:
sputtering a tin-doped indium oxide (ITO) sputtering target in a film-forming gas containing 0.5 to 12% of a gas supplying a hydrogen atom at a partial pressure to form an amorphous film, and
heating the amorphous film to crystallize it.

5. The method for producing according to claim 4, which further comprises: forming an etching cross-section with a tapered shape in a photolithography step after forming the amorphous film.

6. A tin-doped indium oxide sputtering target for forming an amorphous film of tin and hydrogen-doped indium oxide, wherein the amount of tin atom (Sn) based on the total amount of indium atom (In) and tin atom (Sn) [Sn/(In+Sn):molar ratio] is 0.000005 to 0.008.

7. A thin film transistor comprising the semiconductor film according to claim 2.
